(19) United States
(12) Patent Application Publication
(10) Pub. No.: US 2009/0258490 A1
(43) Pub. Date: Oct. 15, 2009

(54) METHOD FOR FORMING CONDUCTIVE FILM

(75) Inventor: Atsushi DENDA, Chino-shi (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/420,265

(22) Filed: Apr. 8, 2009

(30) Foreign Application Priority Data
Apr. 10, 2008 (JP) 2008-102417

(51) Int. Cl. H01L 21/3205

(52) U.S. Cl. 438/660; 257/E21.294

(57) ABSTRACT

A method for forming a conductive film, includes: applying a dispersion liquid above a substrate, the dispersion liquid including a plurality of conductive fine-particles made of one conductive material selected from the group consisting of copper, nickel, and an alloy that includes copper or nickel as a main component; and forming the conductive film made from the conductive fine-particles, by heating the dispersion liquid that has been applied above the substrate in an atmosphere including formic acid, by baking the conductive fine-particles so that the conductive fine-particles are mutually fusion bonded.

### CROSS-REFERENCE TO RELATED APPLICATION

This application is based on and claims priority from Japanese Patent Application No. 2008-102417, filed on Apr. 10, 2008, the contents of which are incorporated herein by reference.

### BACKGROUND

1. Technical Field

The present invention relates to a method for forming a conductive film.

2. Related Art

Conventionally, in the field of electronic devices, a technique in which it is possible to form a low-value resistance conductive film (e.g., electrode, wiring, or the like), at a low cost, and in low-temperature processes has been expected.

In order to reduce the cost, use of liquid phase methods is advantageous, and, for example, a method for using conductive fine-particles as formation material of the conductive film, and applying and heating dispersion liquid in which those are dispersed has been proposed.

As the diameter of the conductive fine-particle reduces, the temperature at which the conductive fine-particles are mutually fusion bonded becomes lower.

As a result, when the dispersion liquid is heated, a dispersion medium volatilizes, the conductive fine-particles are mutually fusion bonded at a temperature lower than the fusing point thereof, and it is possible to form the conductive film made from the conductive fine-particles.

As a method for lowering the electrical resistance of the conductive film, selecting a high conductive material, increasing the thickness of the conductive film, preventing the conductive film from being oxidized, or the like may be considered.

If the conductive fine-particles made of noble metals such as a gold is used, it is considered that a low-value resistance conductive film can be formed because the conductive property of gold is extremely high and it is also difficult to oxidize.

In contrast, in view of promoting reduction of cost and reducing electro-migration, a method for using conductive fine-particles made of copper, nickel, or the like has been proposed.

Since copper and nickel are base metals, a surface of the conductive fine-particles is oxidized before baking.

Then, high-value resistance portions are intervened between the conductive fine-particles, and the electrical resistance of the conductive film thereby increases.

Specifically, in order to lower the temperature of fusion bonding of the conductive fine-particles, if the particle diameter thereof is reduced, the electrical resistance conspicuously increases.

Consequently, as disclosed in, for example, PCT International Publication No. 04/103043 (hereinafter, refer to Patent Document 1) or Japanese Unexamined Patent Application, First Publication No. 2004-119686 (hereinafter, refer to Patent Document 2), methods for forming a low-value resistance conductive film by baking and reducing the conductive fine-particles have been proposed.

In Patent Document 1, heating processing is performed in an atmosphere including an alcohol or the like, after applying a dispersion liquid including copper fine-particles.

As a result, copper oxide formed on the surface of the conductive fine-particles is reduced by aldehyde that is pyrolytically-generated from alcohol, and the conductive fine-particles are mutually fusion bonded.

In Patent Document 2, after applying the dispersion medium including the copper fine-particles, and these are heat-treated and be exposed to plasma derived from a reducing gas.

The surface of the copper oxide is reduced by active reactive species energized in the plasma, and the copper fine-particles are fusion bonded.

It is thought that it is possible to prevent the electrical resistance of the conductive film from being high, which is caused by oxidation of the conductive fine-particles when using the technique of Patent Documents 1 and 2.

However, in Patent Documents 1 and 2, there are improvements in that the temperature in a process is further lowered.

In Patent Document 1, it is thought that the copper oxide formed on the surface of the copper fine-particles can be sufficiently reduced at a temperature less than or equal to 350° C.

However, in order to generate the aldehyde by decomposing the alcohol, or produce the reducing efficiency of the aldehyde, a certain level of heating is necessary, and this counteracts the lowering of temperature in the processes.

There is a case where, for example, the reducing efficiency is not sufficiently produced at a temperature less than or equal to 250° C., and there is the possibility that the electrical resistance of the conductive film increases.

When producing an increase in temperature at approximately 300° C., it is possible to lower the electrical resistance of the conductive film, but there is concern that a disadvantage occurs, for example, adversely affecting a transistor or the like, or a material or the like of a substrate being limited.

When using the technique of Patent Document 2, it is thought that the copper oxide formed on the surface of the copper fine-particles can be reduced at a temperature less than or equal to 250° C.

However, since the portions that are exposed by the plasma is away from the surface at approximately 100 nm, the thickness of the portions whose electrical resistance is lowered by reducing is also the same measure, and it is difficult to increase the thickness of the portion which substantially serves as a conductive film.

### SUMMARY

An advantage of some aspects of the invention is to provide a method for forming a conductive film in which it is possible to reliably lower the electrical resistance.

A aspect of the invention provides a method for forming a conductive film, including: applying a dispersion liquid above a substrate, the dispersion liquid including a plurality of conductive fine-particles made of one conductive material selected from the group consisting of copper, nickel, and an alloy that includes copper or nickel as a main component (application process); and forming the conductive film made from the conductive fine-particles, by heating the dispersion liquid that has been applied above the substrate in an atmosphere including formic acid, by baking the conductive fine-particles so that the conductive fine-particles are mutually fusion bonded (baking process).

It is thought that since all of copper, nickel, and an alloy including copper or nickel as a main component are base metal, the surface of the conductive fine-particles made of the conductive material is oxidized in a state where those are dispersed in a dispersion medium.

In addition, it is known that, by keeping the surface to be adhered to a dispersing agent, the conductive fine-particles are reliably dispersed.

According to the forming method, the formic acid that has been heated up in the baking process decomposes while changing the conditions of substance constituting the formic acid, and a decomposing material reduces the oxidative product formed on the surface of the conductive particles along with a plurality of condition changes.

Here, as the condition changes in the formic acid, four changes described below may be considered.

In a first change in the formic acid, the formic acid is decomposed into carbon monoxide (CO) and water (H₂O), the carbon monoxide reduces the oxidative product, and the water elutes the dispersing agent and is removed.

In a second change in the formic acid, the formic acid is decomposed into hydrogen (H₂) and carbon dioxide, the hydrogen reduces the oxidative product.

In a third change in the formic acid, the oxidative product operates as a catalyst decomposing the formic acid, the formic acid is decomposed into hydrogen ion (H⁺) and HCOO⁻, these are adsorbed on the surface of the oxidative product, the H⁺ reduces the oxidative product, the HCOO⁻ is decomposed into CO and OH⁻, and the CO reduces the oxidative product.

In addition, in a fourth change in the formic acid, the formic acid is decomposed into formaldehyde (HCHO) and oxygen (O₂), and the formaldehyde reduces the oxidative product.

It is thought that the above-described four changes in the formic acid occur in accordance with the ratio corresponding to heating temperature. The four condition changes are combined, and the oxidative product is thereby reduced.

As mentioned above, since it is possible to effectively reduce the oxidative product, as examples described below, the lowering of temperature in processes is improved, and it is possible to form the conductive film, whose resistance value is the same as the plating, at a process temperature of approximately 160 to 300° C.

In addition, it is preferable that the method of the aspect of the invention further include heat-treating the dispersion liquid in an oxidization atmosphere (oxidization process) after applying the dispersion liquid on the substrate. In the method, the dispersion liquid is heated in the atmosphere including formic acid after the dispersion liquid is heat-treated in the oxidization atmosphere.

Namely, it is preferable that the method include an oxidization process, in which the dispersion liquid that has been applied in the application process is heat-treated in the oxidization atmosphere, between the application process and the baking process.

As described above, in order to prevent sedimentation or agglomeration in the conductive fine-particles, the dispersing agent that generates repulsion force between the conductive fine-particles is adhered to the surface of the conductive fine-particles.

In contrast, since the dispersing agent protects the surface of the conductive fine-particles, the dispersing agent counteracts the action of a reducing agent.

As described above, if the method has the oxidization process between the application process and the baking process, the dispersing agent is chemically reacted (burned) in the oxidization process and removed.

As a result, since the surface of the conductive fine-particles is exposed, it is possible to reliably operate the decomposing material of the formic acid.

In addition, it is preferable that, in the method of the aspect of the invention, when applying the dispersion liquid above the substrate, the dispersion liquid be selectively applied above the substrate using a printing method.

According to the printing method, such as a droplet ejection method or a screen printing method, it is possible to selectively apply the dispersion liquid above the substrate, and form a pattern on the conductive film.

As a result, it is possible to form the pattern on the conductive film without a patterning technique of or the like using a photolithography method and an etching method, and to simplify processes or to reduce the waste of formation material.

As described above, it is possible to form the pattern on the conductive film at a low cost.

In addition, it is preferable that, in the method of the first aspect of the invention, a semiconductor layer made of polysilicon be provided on the substrate. In the method, when forming the conductive film (baking process), the conductive fine-particles are baked at a substrate temperature less than or equal to 250° C., and the conductive film that is electrically connected to the semiconductor layer is formed.

A semiconductor layer made of the polysilicon is known to be possible to form in a low-temperature process.

As a result, a semiconductor device can be formed on an inexpensive substrate, and it is possible to manufacture the device at a low cost.

Generally, the semiconductor layer made of the polysilicon is formed so as to include hydrogen preventing a defect level from generating so that the defect level does not generate at a portion that becomes a channel, a portion that touches a gate insulating film, or the like.

When the temperature of the semiconductor layer exceeds 250° C., the hydrogen is removed, and the characteristics of the semiconductor layer are degraded.

According to the invention, since the lowering of temperature in processes for forming the conductive film is improved, the reduction of the hydrogen in the semiconductor layer made of the polysilicon is prevented, it is possible to manufacture the device without occurrence of degradation of the characteristics in the semiconductor layer.

In addition, it is preferable that, in the method of the aspect of the invention, an organic substrate made of an organic material be used as the substrate.

In this manner, since the organic substrate is generally inexpensive and is flexible, it is possible to manufacture an irrefrangible device at a low cost.

Generally, the organic substrate is known in which the heat resistance thereof is lower than that of a glass substrate or the like.

According to the invention, since the lowering of temperature in processes for forming the conductive film is improved, deformation, change of properties, damage, or the like of the organic substrate which is caused by heating is prevented, and it is possible to manufacture an excellent device with an excellent yield.

### BRIEF DESCRIPTION OF THE DRAWINGS

FIGS. 1A to 1D are flow sheets showing an example of a method for forming a conductive film of the invention.

FIGS. 2A to 2C are tables comparing specific resistances between comparative examples and experimental examples.

### DESCRIPTION OF EXEMPLARY EMBODIMENTS

Hereinafter, an embodiment of the invention will be described, but the embodiment described below is not limited to the technical scope of the invention.

In an explanation described below, a variety of structures are shown as an example with reference to drawings. In order to indicate so as to understand characteristic portions of the structure, the size or the scale of the structure in the drawings may be different from a practical structure.

In the embodiment, a wiring pattern electrically connected to a semiconductor layer is formed on a substrate on which a semiconductor layer made of polysilicon is formed, using a droplet ejection method.

In addition, as formation of the wiring pattern (conductive film pattern), a method for forming a conductive film of the invention is applied.

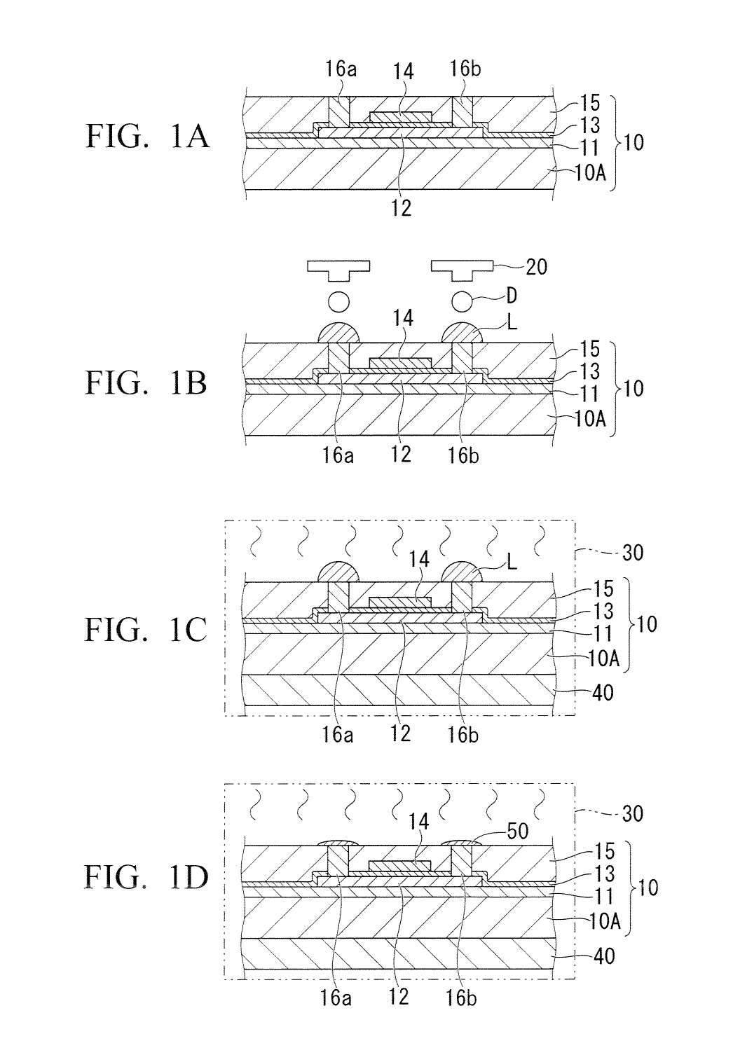

FIGS. 1A to 1D are flow sheets showing the method for forming the wiring pattern of the embodiment.

Firstly, as shown in FIG. 1A, a base 10 on which a thin film transistor is formed is prepared.

The base 10 includes a foundation insulating film 11, a semiconductor layer 12, a gate insulating film 13, a gate electrode 14, a interlayer insulating film 15, a source electrode 16a, and a drain electrode 16b.

The foundation insulating film 11 is provided on a substrate 10A.

The semiconductor layer 12 is selectively provided on the foundation insulating film 11.

The gate insulating film 13 is provided so as to cover the foundation insulating film 11 and the semiconductor layer 12.

The gate electrode 14 is selectively provided on the gate insulating film 13, and is disposed so as to be superimposed on the semiconductor layer 12.

The interlayer insulating film 15 is provided so as to cover the gate insulating film 13 and the gate electrode 14.

The source electrode 16a and the drain electrode 16b are provided so as to penetrate the gate insulating film 13 and the interlayer insulating film 15 and are respectively in touch with a source region and a drain region of the semiconductor layer 12 so as to be conducted thereto.

As the substrate 10A, a substrate generally used in a field of electronic device such as a silicon wafer, a quartz glass, a glass, a plastic film, a metal plate can be used.

A glass substrate is employed in the embodiment.

The foundation insulating film 11, the gate insulating film 13, and the interlayer insulating film 15 are films made of a insulating material such as a silicon oxide or a silicon nitride.

The semiconductor layer 12 is a layer that is formed by, after forming an amorphous silicon using, for example, a PECVD method, irradiating the amorphous silicon with an excimer laser so as to crystallize this film.

In addition, in order to prevent a defect level, the semiconductor layer 12 is formed so as to include hydrogen.

The gate electrode 14, the source electrode 16a, and the drain electrode 16b are made of a conductive material generally used in a semiconductor field such as aluminum (Al), titanium (Ti), tantalum (Ta), tungsten (W), or molybdenum (Mo).

In addition, the method for forming the wiring pattern of the embodiment, dispersion liquid including a plurality of conductive fine-particles is preliminarily prepared, and surface treatment is performed on the base 10 so that the dispersion liquid has a predetermined contact angle relative to the surface of the base 10.

In the embodiment, copper fine-particles are used as the conductive fine-particles.

As the copper fine-particle, any of the fine-particle made of Cu and a core-shell fine-particle whose inside is made of Cu and whose outside is made of Cu₂O may be used.

Here, in order to improve the dispersibility of the copper fine-particles, dispersing agent is adhered to the surface of the copper fine-particles.

As the dispersing agent, organic solvent medium (e.g., xylene or toluene, or the like), citric acid, or the like is employed.

It is preferable that the percentage of a dispersing agent be less than or equal to the 10 wt % (weight %) of the copper fine-particles to which the dispersing agent is adhered.

In addition, if copper fine-particles whose particle diameter is greater than or equal to 5 nm are used, the volume of the dispersing agent is prevented from being overmuch relative to the copper fine-particles, and it is possible to reduce the residual amount of the dispersing agent in the wiring pattern formed by the method for forming the wiring pattern of the embodiment.

In addition, if the copper fine-particles whose particle diameter is less than or equal to 100 nm are used, blockage of a nozzle of a liquid ejection apparatus is prevented, and it is also possible to lower the temperature at which the copper fine-particles are fusion bonded.

Furthermore, generally, as the particle diameter reduces, the temperature at which the conductive fine-particles are mutually fusion bonded becomes lower.

Here, in view of fusion bonding at low temperature (e.g., less than or equal to 300° C.), the copper fine-particles whose particle diameter is less than or equal to 70 nm are selected.

The percentage of the copper fine-particles in the dispersion liquid may be adjusted depending on a desired film thickness of the conductive film within greater than or equal to 1 wt % and less than or equal to 80 wt %.

If exceeding 80 wt %, agglomeration easily occurs, and it is difficult to obtain an even film.

As the above-described dispersion medium dispersing the copper fine-particles, water, alcohols, hydrocarbon type compounds, ether type compounds, mixtures made of materials whose types are greater than or equal to two selected from the group consisting those materials, or the like is adopted.

In addition, by adjusting composition of the dispersion medium, added substances, or the like, the dispersion liquid may be adjusted to the physicality which is suitable to the application.

In the case of applying the dispersion liquid using, for example, a droplet ejection method, when the surface tension of the dispersion liquid is set to be greater than or equal to 0.02 N/m, it is possible to reduce the amount of curve in the droplet's flight path, and when the surface tension of the dispersion liquid is set to be less than or equal to 0.07 N/m, the ejection rate or the ejection timing can be controlled with a high level of precision.

In addition, if the degree of viscosity is set to be greater than or equal to 1 mPa·s, breaking of droplet is improved, generation of contamination at periphery portions of the nozzle is suppressed which is caused by outflow of the dispersion liquid.

If the degree of viscosity is set to be less than 50 mPa·s, it is difficult blockage of the nozzle hole to occur.

In addition, if the pressure of saturated vapor in the dispersion medium is set to be greater than or equal to 0.001 mmHg, it is possible to ensure the drying rate, and it is difficult for the dispersion medium to remain in the conductive film.

If setting less than or equal to 50 mmHg, it is difficult to occur the blockage which is caused by drying the dispersion medium inside the nozzle hole.

Next, as shown in FIG. 1B, droplets D of the prepared dispersion liquid are ejected by a droplet ejection head 20, and the dispersion liquid is applied on a formation region of the wiring pattern connected with the source electrode 16a and the drain electrode 16b of the base 10, that is, on the source electrode 16a and the drain electrode 16b.

As described above, by adjusting the physicality of the dispersion liquid, it is possible to stably operate the ejection and control the ejection rate of the dispersion liquid or the application position (ejection position) with a high level of precision.

In the embodiment, the applied dispersion liquid L is optionally dried, and the flowability thereof is lowered.

As a result, the displacement between the position at which the dispersion liquid L is applied and the position at which the dispersion liquid L has been dried is prevented.

Next, in the embodiment, the dispersing agent adhered to the surface of the copper fine-particles is removed in an oxidization process.

As shown in FIG. 1C in detail, a heating device 40 such as a hot plate is preliminarily disposed in a chamber 30 that is capable of controlling an atmosphere, and the base 10 on which the dispersion liquid L is applied is mounted on the heating device 40.

Consequently, the atmosphere inside chamber is set to the condition in which, for example, greater than or equal to 5 ppm of oxygen is included, and the base 10 is heated at a substrate temperature of approximately 50 to 300° C. in an approximately 1 to 90 minute period.

The atmosphere inside the chamber may include an inert gas such as N₂, Ar, or Ne, or air or a highly-concentrated oxygen.

In the embodiment, air is supplied in the chamber while being heated at a substrate 250° C. for a 10 minute period.

As a result, the dispersion medium of the dispersion liquid L is evaporated, and the dispersing agent becomes carbon dioxide or water vapor by chemical reacting with oxygen.

In this manner, as shown in FIG. 1D, collectives 50 of the copper fine-particles are formed by removing the dispersion medium from the dispersion liquid L, and the surface of the copper fine-particles is exposed by only removing the dispersing agent from the surface of the copper fine-particles.

Furthermore, in the case where the dispersing agent or the dispersion medium is volatile, they may be removed in the baking process.

After the oxidization process, the base 10 remains to be mounted on the heating device 40, and the baking process is continuously performed.

Even if a material that is not oxidized is prepared as copper fine-particles, the surface thereof is oxidized by moisture or oxygen included in the dispersion liquid, an exposure to an oxygen atmosphere in the oxidization process, or the like.

In the baking process, the copper fine-particles are fusion bonded while the copper oxide formed on the surface of the copper fine-particles is reduced.

Specifically, a mixture gas constituted of vapor of formic acid (HCOOH) and an inert gas is supplied to inside the chamber 30 at, for example, at a flow rate of 3 liters per minute, at approximately 140 to 300° C. of the substrate temperature, and the base 10 is heated for an approximately 1 to 90 minute period.

Here, since the semiconductor layer is constituted of polysilicon, the base 10 is heated so as to set the substrate temperature to be less than or equal to 250° C.

When the semiconductor layer has a temperature greater than 250° C., a phenomenon appears in that the hydrogen that prevents the defect level from generating is removed. When the semiconductor layer has a temperature greater than 300° C., the hydrogen is conspicuously removed.

When the substrate temperature is set to be less than or equal to 300° C., the degree of removal of the hydrogen is reduced. As described in the embodiment, when the substrate temperature is set to be less than or equal to 250° C., the removal of the hydrogen is prevented, and degradation of the properties of the semiconductor layer is prevented.

When heating in the atmosphere including formic acid, it is thought that the formic acid is decomposed due to the chemical reactions by formulas (1) to (4) indicated below.

HCOOH→CO+H₂O (1)

HCOOH→H₂+CO₂ (2)

HCOOH→H⁺+HCOO⁻ (3)

2HCOOH→2HCHO+O₂ (4)

In the chemical reaction indicated by formula (1), CO (carbon monoxide) and H₂O (water) are generated, the CO reduces copper oxide, and the H₂O elutes out and removes residues of the dispersing agent.

In the chemical reaction indicated by formula (2), H₂ (hydrogen) and CO₂ (carbon dioxide) are generated, and the H₂ reduces copper oxide.

In the chemical reaction indicated by formula (3), copper oxide operates as a catalyst decomposing the formic acid, the formic acid is decomposed into H⁺ (hydrogen ion) and HCOO⁻, and they are adsorbed on the surface of the copper oxide.

Since these are adsorbed on the surface of the copper oxide, H⁺ effectively operates and reduces the oxide, HCOO⁻ is decomposed into CO and OH⁻, and the CO also reduces the copper oxide.

In addition, in the chemical reaction indicated by formula (4), the formic acid is decomposed into HCHO (formaldehyde) and O₂ (oxygen), and the HCHO reduces the oxide.

It is thought that, in the decomposition reaction in the formic acid, each of the percentages of the chemical reactions indicated by formula (1) to (4) varies depending on the concentration of the formic acid in the atmosphere, the substrate temperature, or the like.

Since all of the chemical reactions indicated by formula (1) to (4) contribute the reduction of the copper oxide, it is possible to effectively reduce the copper oxide.

In addition, since the dispersing agent is removed in the oxidization process and the surface of the copper fine-particles is exposed, the decomposing material of the formic acid reliably operates thereto, and it is possible to effectively reduce the copper oxide.

The copper fine-particles whose copper oxide surfaces have been reduced are mutually fusion bonded to adjacent copper fine-particles, and they are metal-bonded at fusion bonded portions.

In the above-described collective 50 made of the copper fine-particles, since the copper fine-particles are fusion bonded and integrated, a wiring pattern made from the collective 50 is obtained.

### Examples

Subsequently, resistance values of the conductive film obtained by the method for forming the conductive film of the invention will be described with reference to several experimental examples.

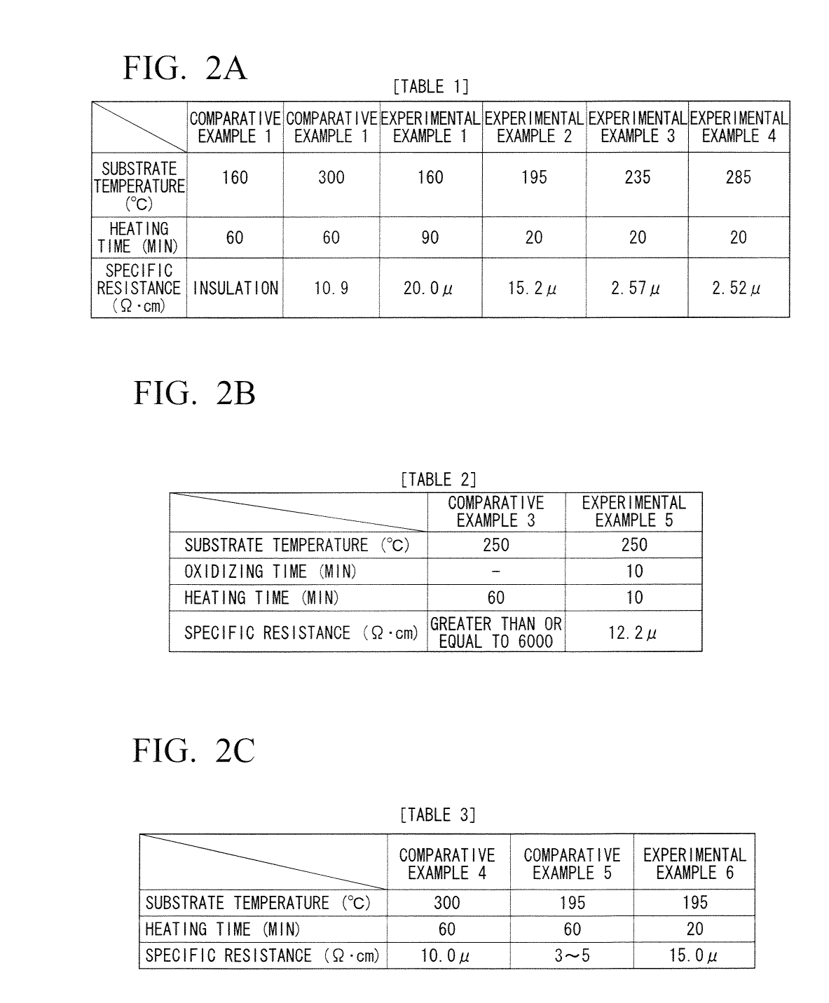

FIGS. 2A to 2C are tables comparing specific resistances between comparative examples in which a conductive film is formed without using formic acid in a baking process, and experimental examples in which a conductive film is formed using the formation method of the invention.

All of comparative examples 1 and 2, and experimental examples 1 to 4 shown in Table 1 of FIG. 2A indicate an experimental result in the case of using copper fine-particles whose main component is Cu₂O.

Comparative example 1 indicates an experimental result in which a conductive film was obtained by heating the conductive film in a nitrogen atmosphere, at a substrate temperature of 160° C., and for 60 minutes. The specific resistance of the conductive film was extremely high and has a substantially insulation property.

In addition, comparative example 2 indicates an experimental result in which a conductive film was obtained by heating the conductive film in a nitrogen atmosphere, at a substrate temperature of 300° C., and for 60 minutes. The specific resistance of the conductive film was 10.9 Ω·cm.

In contrast, experimental example 1 obtained by the invention indicates an experimental result in which a conductive film was obtained by heating in an atmosphere including formic acid, for 90 minutes, after a substrate temperature has risen at rate of 20° C./minute to 160° C.

The specific resistance of the conductive film was 20.0 μΩ·cm, and electrical resistance is dramatically lower than that of comparative example 1.

In addition, experimental examples 2 to 4 indicate experimental results in which a substrate temperature has risen at rate of 20° C./minute to a predetermined substrate temperature, and a conductive film was obtained by maintaining this substrate temperature for 20 minutes and heating it in an atmosphere including formic acid.

The specific resistance of the conductive film was 15.2 μΩ·cm in experimental example 2 (substrate temperature 195° C.), 2.57 μΩ·cm in experimental example 3 (substrate temperature 235° C.), and 2.52 μΩ·cm in experimental example 4 (substrate temperature 285° C.).

As described above, as the substrate temperature increases, the specific resistance becomes lower, although it is thought that a substrate temperature of approximately 235° C. is sufficient as a heating temperature because the difference between experimental example 3 and experimental example 4 is small.

In addition, all thicknesses of the conductive film in experimental examples 1 to 4, are set to approximately 500 nm, and the thickness can increase to approximately 5 μm.

Therefore, it is thought that, when the substrate temperature is greater than or equal to 160° C., the conductive film can function as a wiring pattern.

In addition, since the specific resistance (2.57 μΩ·cm) of the conductive film obtained in the substrate temperature of 235° C. is in the same range of the specific resistance (1.7 μΩ·cm) of bulk copper, it is thought that the electrical resistance of the conductive film is dramatically low when the substrate temperature is greater than or equal to 235° C., and the conductive film can reliably function as a wiring pattern.

All of comparative example 3 and experimental example 5 shown in Table 2 of FIG. 2B indicates an experimental result in the case of using copper fine-particles whose main component is Cu.

Comparative example 3 indicates an experimental result in which a conductive film was obtained by heating at a substrate temperature of 250° C. for 60 minutes. The specific resistance of the conductive film was greater than or equal to 6000 Ω·cm.

In addition, experimental example 5 indicates an experimental result in which, after a substrate temperature has risen by rate of 20° C./minute to 250° C., the oxidization process for heating is performed in an air atmosphere for 10 minutes, subsequently, a conductive film was obtained by heating the conductive film in an atmosphere including formic acid for 10 minutes.

The specific resistance of the conductive film in experimental example 5 was 12.2 μΩ·cm, the electrical resistance is dramatically lower than that of comparative example 3, and it is thought that the conductive film can reliably function as a wiring pattern.

All of comparative examples 4 and 5, and experimental example 6 shown in Table 3 of FIG. 2C indicates an experimental result in the case of using nickel fine-particles whose main component is nickel (Ni).

Comparative example 4 indicates an experimental result in which a conductive film was obtained by heating the conductive film in a nitrogen atmosphere at a substrate temperature of 300° C. for 60 minutes. The specific resistance of the conductive film was 10.0 μΩ·cm.

Comparative example 5 indicates an experimental result in which a conductive film was obtained by heating the conductive film in a nitrogen atmosphere at a substrate temperature of 195° C. for 60 minutes. The specific resistance of the conductive film was approximately 3 to 5 Ω·cm.

As described above, in the case of not using formic acid, since the specific resistance precipitously increases when the substrate temperature decreases, it is impossible to use the conductive film obtained by this method as a wiring pattern.

In contrast, experimental example 6 obtained by the invention indicates an experimental result in which a substrate temperature was increased at rate of 20° C./minute to a substrate temperature of 195° C., this substrate temperature was maintained for 20 minutes, and a conductive film was obtained by maintaining this substrate temperature for 20 minutes and by heating the conductive film in an atmosphere including formic acid.

The specific resistance of the conductive film was 15.0 μΩ·cm, and is in the same specific resistance range of comparative example 4, in spite of having considerably lower substrate temperature and a shorter processing period than comparative example 4.

As described above, even if nickel fine-particles are used, according to the invention, a lower-temperature process or a shorter processing period is improved.

As described above, according to the method of forming a conductive film of the invention, since the conductive fine-particles are baked while reducing the conductive fine-particles in an atmosphere including formic acid, it is possible to effectively reduce conductive fine-particles.

Therefore, as described in the above experimental example, it is possible to form the conductive film with a low-electrical resistance and improve the temperature of the baking process to be lowered.

Therefore, in the case of using, for example, a substrate with a low heat resistance such as an organic substrate, a substrate on which low-heat resistance elements are formed and which includes a semiconductor layer made of the polysilicon, a semiconductor layer made of an organic material, or the like, it is possible to reliably form the conductive film on these substrate, and to cause the conductive film to function as an electrode film, a wiring pattern, or the like.

Generally, a substrate whose heat resistance is low is inexpensive, when the conductive film is formed thereon and thereby constituting a device, it is possible to manufacture the device at a low cost.

In addition, when the conductive film is formed on an organic substrate having a flexibility and thereby constituting a device, it is possible to constitute a device which is difficult to be destroyed.

In addition, it is possible to manufacture a thin film transistor having a semiconductor layer made of polysilicon at a low cost. When configuring the device by forming the conductive film on the substrate having the thin film transistor, it is possible to manufacture the device at a low cost.

As described above, according to the invention, it is possible to reliably form a conductive film on an inexpensive substrate or on a substrate having an element formed at a low cost, and it is possible to manufacture an excellent device at a low cost.

In addition, when applying the dispersion liquid on the substrate as the embodiment using a printing method such as a droplet ejection method, the process is simplified more than the case of patterning technique using a photolithography method and an etching method.

In addition, it is possible to reduce the amount of waste of material, a cost for processing waste liquid or the like is reduced, and it is possible to form the conductive film at a low cost.

In addition, in the above-described embodiment, a wiring pattern is formed as an example of a conductive film, but, additionally, it is possible to form conductive films for various applications such as a film which serves as an electrode or a film used for an electrostatic countermeasure.

What is claimed is:

1. A method for forming a conductive film, comprising:
applying a dispersion liquid above a substrate, the dispersion liquid including a plurality of conductive fine-particles made of one conductive material selected from the group consisting of copper, nickel, and an alloy that includes copper or nickel as a main component; and
forming the conductive film made from the conductive fine-particles, by heating the dispersion liquid that has been applied above the substrate in an atmosphere including formic acid, by baking the conductive fine-particles so that the conductive fine-particles are mutually fusion bonded.

2. The method according to claim 1, further comprising:
heat-treating the dispersion liquid in an oxidization atmosphere after applying the dispersion liquid on the substrate, wherein
the dispersion liquid is heated in the atmosphere including formic acid after the dispersion liquid is heat-treated in the oxidization atmosphere.

3. The method according to claim 1, wherein
when applying the dispersion liquid above the substrate, the dispersion liquid is selectively applied above the substrate using a printing method.

4. The method according to claim 1, wherein
a semiconductor layer made of polysilicon is provided on the substrate, and wherein
when forming the conductive film, the conductive fine-particles are baked at a substrate temperature less than or equal to 250° C., and the conductive film that is electrically connected to the semiconductor layer is formed.

5. The method according to claim 1, wherein
an organic substrate made of an organic material is used as the substrate.
